(19) United States
(12) Patent Application Publication
(10) Pub. No.: US 2025/0015204 A1
(43) Pub. Date: Jan. 9, 2025

(54) FUNCTIONAL DEVICE WITH DIRECT ELECTRICAL OUTPUTS AND PROCESS FOR FABRICATING SUCH A FUNCTIONAL DEVICE

(71) Applicants: COMMISSARIAT A L'ENERGIE ATOMIQUE ET AUX ENERGIES ALTERNATIVES, Paris (FR); COLAS, Paris (FR)

(72) Inventors: Amandine BOULANGER, Grenoble cedex 09 (FR); Dick HESLINGA, Grenoble cedex 09 (FR); Jean RODIERE, Magny-les-Hameaux (FR); Rémi DE BETTIGNIES, Grenoble cedex 09 (FR); Eric COQUELLE, Versailles (FR); Patrick LELIEVRE, Grenoble cedex 09 (FR)

(21) Appl. No.: 18/712,345

(22) PCT Filed: Nov. 21, 2022
(86) PCT No.: PCT/EP2022/082559

§ 371 Date: May 22, 2024

(30) Foreign Application Priority Data
Nov. 22, 2021 (FR) FR2112321

(51) Int. Cl. H01L 31/02; H01L 31/044; H01L 31/048; H01L 31/18; H02S 10/40; H02S 20/21; H02S 20/26

(52) U.S. Cl. CPC H01L 31/02008; H01L 31/044; H01L 31/048; H01L 31/18; H02S 10/40; H02S 20/21; H02S 20/26

(57) ABSTRACT

The invention relates to a functional device (100) comprising a multilayer stack comprising, in succession:
a first protective film (101), placed on a front side of said device (100),
an encapsulating assembly (107),
a second protective film (105), placed on the back side of the device,
at least one electrically or optically active element (110) embedded in the encapsulating assembly, and
an electrical connecting element (160) directly connected to said electrically or optically active element and suitable for transporting electricity from or to said electrically or optically active element, one end (162) of said electrical connecting element exiting directly from said functional device.

### PRIOR ART

The present invention relates to the technical field of the functional devices, e.g. multilayer structures, comprising electrically or optically active elements, such as photovoltaic cells, light-emitting diodes or resistive films.

The invention finds a preferred application in solar roads field. The invention can for example be integrated in roadways trafficable by pedestrians and/or vehicles, motorised or not, such as roadways or roads, cycle paths, industrial or airport platforms, squares, pavements or car parks.

The invention also finds a preferred application in transport vehicles (e.g. cars, lorries, trains or boats) or building envelopes, to which the functional device can be fastened.

It relates in particular to a functional device with direct electric outlets and a method for manufacturing such a functional device, intended to be integrated in a roadway, and a functionalised trafficable or pedestrian roadway comprising such a device.

### BACKGROUND OF THE INVENTION

Functionalised roadways are roadways comprising electrically or optically active elements, such as photovoltaic cells or other electrically or optically active elements such as light-emitting diodes (LEDs), electrical, electronic, optical, optoelectric, piezoelectric and/or thermoelectric elements. These elements may allow generating, receiving and/or communicating data, or also generating and transferring energy.

In particular, the solar road principle consists in using roads or roadways as means for producing electric energy from solar irradiation during the day.

For that purpose, solar modules are inserted in so-called trafficable roadways (roads, pavements, etc.), and covered by a transparent textured surface, resistant to vehicle traffic and meeting the grip requirements applicable to roads and other trafficked areas.

Conventionally, the photovoltaic modules comprise:
a transparent plate on the front side of the module, generally made of glass; the front side being that which is exposed to the incident solar radiation when the modules are implanted on site,
a set of interconnected photovoltaic cells, embedded in an encapsulation layer,
a plate on the back side of the photovoltaic module, generally made of glass or a “backsheet” formed of multilayer polymers.

These photovoltaic modules generally comprise, mainly on the back side, a junction box. In particular, it allows the transition between the electrical connections internal to the photovoltaic module (generally, flat copper tape) and the electrical connections external to the photovoltaic module (generally, round or flat cables). This junction box generally also contains one or more bypass diodes, necessary to the good operation and the protection of the photovoltaic module in particular in the event of malfunction of the photovoltaic cells included in this module.

However, in case of installation of a photovoltaic module on a roadway, the presence of a junction box on the module induces high installation costs because it is in particular necessary to make a trench in the roadway to embed the junction box therein. This trench must then be filled with a material compatible with the roadway and with the passage of the traffic. A similar problem exists in any application of photovoltaic modules fastened to a support, over their whole back side surface.

### SUMMARY OF THE INVENTION

In this context, the present invention proposes to improve the manufacturing of the functional devices, in particular those intended to be integrated in a roadway, in such a way as to reduce their costs of installation on the support concerned. This support is preferentially a trafficable roadway. It may also be any support such as surfaces of buildings, boats, cars, and more generally, any surface on which the functional device could be applied using glue or any other fastening means.

In particular, the invention relates to a functional device including a multilayer stack.

This multilayer stack comprises successively:
a first, transparent, protective film, arranged on the front side of said device,
an encapsulating assembly,
a second protective film, transparent or not, arranged on the back side of the device,
at least one electrically or optically active element, embedded in the encapsulating assembly, and
an electrical connection element connected to said electrically or optically active element and suitable for transporting electricity from or to said electrically or optically active element.

According to the invention, the electrical connection element is integrated into the multilayer stack. Moreover, the electrical connection element comprises an outer sheath free from halogen elements and an end of which exits directly from said functional device, so as to eliminate the need for an intermediate junction box on the front side or the back side of the functional device.

Therefore, the absence of halogen elements in the outer sheath of the electrical connection element, for example an electrical cable, makes it possible to obtain a good adherence between the encapsulating assembly of the functional device and the outer sheath of the electrical connection element. This is an essential factor to ensure a good seal and avoid the risk of delamination at the exit of the electrical connection element from the functional device.

Moreover, this arrangement, directly integrating the electrical connection element in the functional device, wherein this electrical connection element also exits directly outside this device, eliminates the need for an intermediate junction box on the front side or the back side of the functional device. This also allows ensuring the reliability of the functional device in relation to the ambient conditions of this device, in particular the physical, mechanical or chemical influences undergone by the device.

Other non-limiting and advantageous features of the device according to the invention, taken individually or according to all the technically possible combinations, are the following:
the electrically or optically active element is a photovoltaic cell, said photovoltaic cell being connected to at least one bypass diode embedded in the encapsulating assembly;
the outer sheath of the electrical connection element is free from fluoropolymer and/or chloropolymer and/or bromopolymer;
the encapsulating assembly comprises a passage for the exit of electrical connection element, through the encapsulating assembly, outside the functional device;
the encapsulating assembly comprises:
   a) a first outer encapsulating film,
   b) an inner encapsulating film, and
   c) a second outer encapsulating film;
the electrical connection element is embedded in an encapsulating material along its passage through said functional device, said encapsulating material being chosen among one or more of the materials forming the first outer encapsulating film, the inner encapsulating film or the second outer encapsulating film;
the second outer encapsulating film comprises a first orifice and the second protective film comprises a second orifice, the first orifice and the second orifice being aligned in such a way as to form a through-orifice for the passage of the electrical connection element through the second outer encapsulating film and the second protective film;
a space between walls of said through-orifice and the electrical connection element passing through said through-orifice is filled with the same material as that forming the second outer encapsulating film;
the first outer encapsulating film comprises a third orifice and the first protective film comprises a fourth orifice, the third orifice and the fourth orifice being aligned in such a way as to form a through-orifice for the passage of the electrical connection element through the first outer encapsulating film and the first protective film;
a space between walls of said through-orifice and the electrical connection element passing through said through-orifice is filled with the same material as that forming the first outer encapsulating film;
a passage for the exit of the electrical connection element through the inner encapsulating film is included in the inner encapsulating film;
a passage for the exit of the electrical connection element through the inner encapsulating film is arranged between the first outer encapsulating film and the inner encapsulating film;
a passage for the exit of the electrical connection element through the inner encapsulating film is arranged between the inner encapsulating film and the second outer encapsulating film;
a stripped metal end of said electrical connection element is directly welded on an electrically conductive part of said electrically or optically active element;
a stripped metal end of the electrical connection element is connected to an electrically conductive part of said electrically or optically active element by means of an intermediate connection element, e.g. a flat copper tape;
the intermediate connection element comprises a terminal;
the electrical connection element is a round or flat electrical cable;
the electrical connection element is a flat metal braid covered with a heat-shrinkable sheath; and
the electrical connection element has a cross-section less than or equal to 2.5 mm².

The invention also relates to a method for manufacturing a functional device as defined hereinabove. The method comprises:
a step of connecting the electrical connection element to the electrically or optically active element; and
a step of forming the multilayer stack for embedding the electrically or optically active element into the encapsulating assembly between the first protective film and the second protective film, an end of the electrical connection element exiting directly from said functional device.

Other non-limiting and advantageous features of the manufacturing method according to the invention, taken individually or according to all the technically possible combinations, are the following:
the step of forming the multilayer stack is made by hot lamination;
a step of forming a passage into said encapsulating assembly is provided, said passage allowing the exit of the electrical connection element through said encapsulating assembly;
a step of forming a through-orifice through said encapsulating assembly and said second protective film for the passage of the electrical connection element through said functional device is provided; and
a step of forming a through-orifice through said encapsulating assembly and said first protective film for the passage of the electrical connection element through said functional device is provided.

The invention also relates to a functionalised trafficable or pedestrian roadway, comprising a trafficable or pedestrian roadway on which is fastened a functional device as defined hereinabove.

The invention also relates to a transport vehicle comprising a functional device as defined hereinabove.

The invention finally relates to a building envelope comprising a functional device as defined hereinabove.

Obviously, the different features, alternatives and embodiments of the invention can be associated with each other according to various combinations, insofar as they are not incompatible or exclusive with respect to each other.

### DETAILED DESCRIPTION OF THE INVENTION

Moreover, various other features of the invention emerge from the appended description made with reference to the drawings that illustrate non-limiting embodiments of the invention, and wherein:

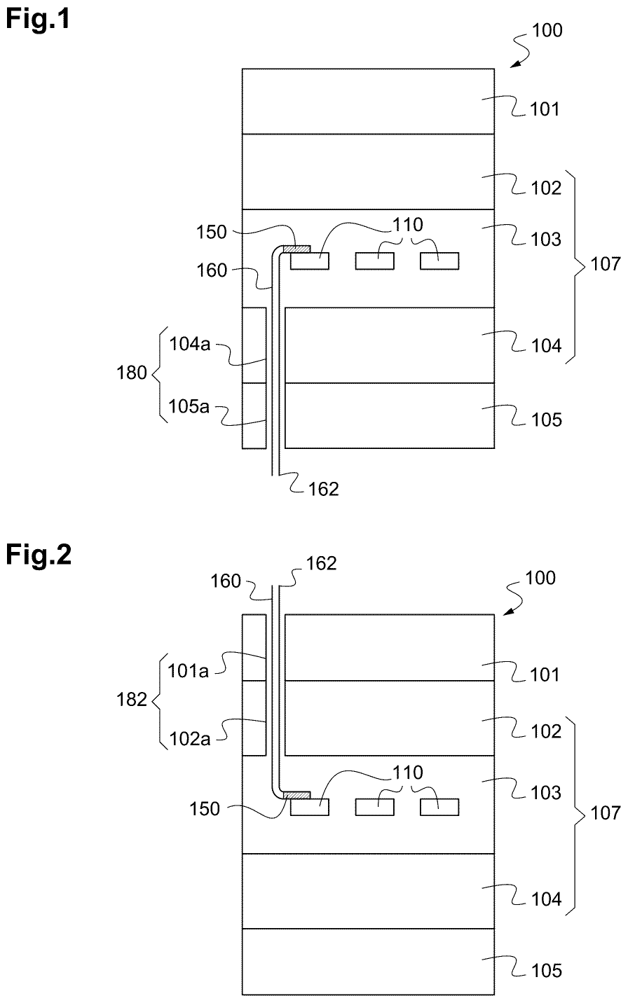

FIG. 1 schematically shows a cross-sectional view of a functional device according to a first embodiment of the invention in which an electrical connection element exits through the back side of the functional device,

FIG. 2 schematically shows a cross-sectional view of a functional device according to a second embodiment of the invention in which an electrical connection element exits through the front side of the functional device,

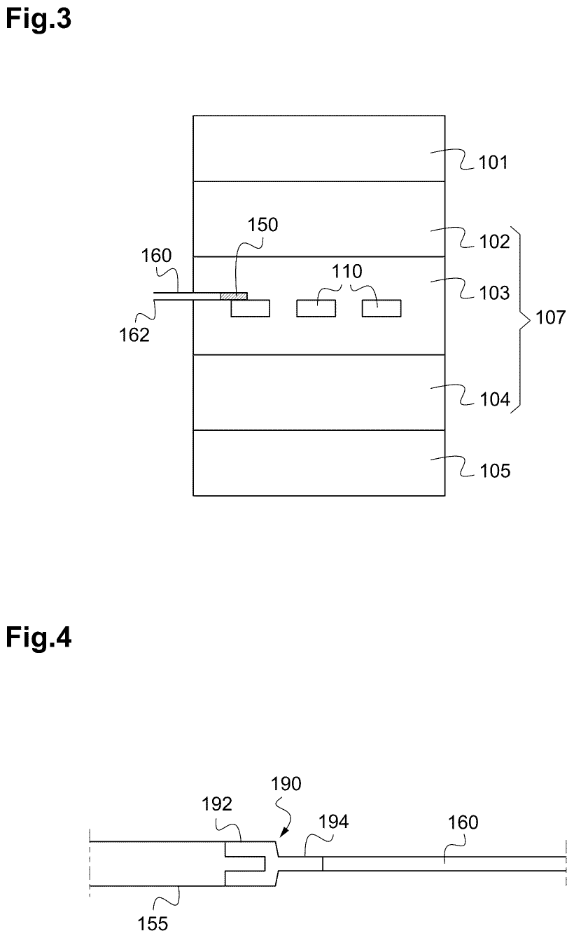

FIG. 3 schematically shows a cross-sectional view of a functional device according to a third embodiment of the invention in which an electrical connection element exits through the lateral side of the functional device,

FIG. 4 schematically shows an example of electrical connection between an electrical connection element and an electrically conductive connector according to the invention,

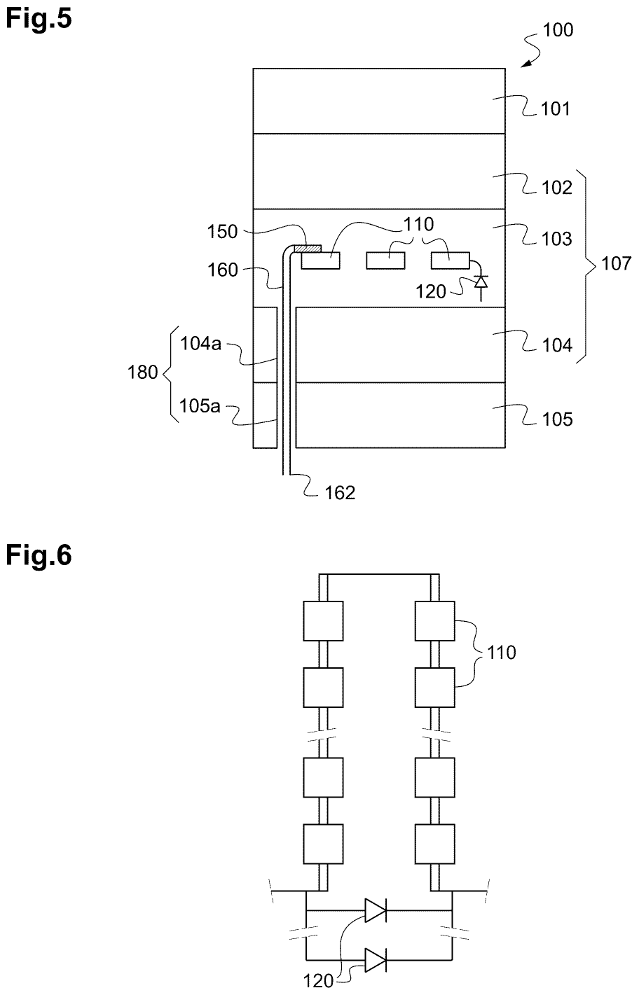

FIG. 5 schematically shows a cross-sectional view of a functional device according to the first embodiment of the invention in which an electrical connection element exits through the back side of the functional device and comprising photovoltaic cells and at least one bypass diode, and

FIG. 6 shows an electrical diagram showing the arrangement of the photovoltaic cells and bypass diodes.

As a preliminary point, it should be noted that identical or similar elements of the various embodiments of the invention shown in the different figures will, as far as possible, be referred to by the same reference signs and will not be described each time.

FIG. 1 schematically shows a cross-sectional view of a functional device 100. This functional device 100 is for example integrated on a trafficable area such as a trafficable or pedestrian roadway.

As shown in FIG. 1, the functional device 100 comprises a multilayer stack comprising successively:
a first plate, also called first protective film 101, arranged at the front side of the functional device 100, transparent, with a first thickness e₁, made of a first material having a first Young's modulus E₁ and a first coefficient of thermal expansion CTE₁,
an encapsulating assembly 107 embedding at least one electrically or optically active element 110 (also called active element 110 in the following of this description), and
a second plate, also called second protective film 105, arranged at the back side of the functional device 100, transparent or not, with a second thickness e₅, made of a second material having a second Young's modulus E₅ and a second coefficient of thermal expansion CTE₅.

Preferentially according to the invention, the encapsulating assembly 107 comprises:
a first outer encapsulating film 102, having a third thickness e₂, made of a third material having a third Young's modulus E₂ and a third coefficient of thermal expansion CTE₂,
an inner encapsulating film 103, embedding the active elements 110, the inner encapsulating film 103 having a fourth thickness e₃, being made of a fourth material having a fourth Young's modulus E₃ and a fourth coefficient of thermal expansion CTE₃, and
a second outer encapsulating film 104, having a fifth thickness e₄, made of a fifth material having a fifth Young's modulus E₄ and a fifth coefficient of thermal expansion CTE₄.

As an alternative (not shown), the encapsulating assembly can be formed by only two encapsulating films. As another alternative (not shown), the encapsulating assembly can be formed by a single encapsulating film.

In the present description, all the Young's modulus and coefficient of thermal expansion values are given at ambient temperature (20-25° C.).

### First Plate 101 and Second Plate 105:

The first plate 101 and the second plate 105 are the elements of the functional device 100 in direct contact with the outside environment.

The materials of the plates 101, 105 are materials with a high Young's modulus. Preferably, their Young's moduli E are higher than 2 GPa, advantageously higher than 5 Gpa, even more advantageously higher than 10 GPa. The Young's moduli remain high at least over the whole range of operating temperatures of the functional device 100 (from −40° C. to +85° C.).

The first plate 101 and the second plate 105 have high mechanical rigidity, low deformability and are impact resistant.

The first plate 101 and the second plate 105 are made of materials having a low coefficient of thermal expansion. Preferably, their coefficients of thermal expansion CTE are less than 200×10⁻⁶/K, more preferentially less than 100×10⁻⁶/K, and even more preferentially less than 50×10⁻⁶/K. They have a high dimensional stability under temperature variations.

Preferably, the Young's moduli of the first plate 101 and of the second plate 105 are higher than 10 Gpa and their coefficients of thermal expansion are less than 50×10⁻⁶/K.

Advantageously, to avoid having a material which expands more than the other under the effect of heat and/or contracts more than the other under the effect of cold, and hence to avoid inducing inhomogeneous mechanical stresses in the assembly, materials having Young's modulus (E) and coefficient of thermal expansion (CTE) values the closest possible to each other will be used for the first plate 101 and for the second plate 105. By “the closest”, it is meant that these values will differ by 0 to 30% maximum, preferably by 0 to 20%, and more preferably by 0 to 10%, and advantageously they will be identical.

As the two protective plates (or films) 101, 105 are in contact with the external environment, they can also act as barriers to external influences (particularly humidity). They advantageously have the following additional characteristics:
high resistance to water penetration,
intrinsic stability against structural degradation by water molecules,
high resistance to exposure to chemical fluids.

For example, the first 101 and second 105 plates are made of a material having the lowest possible Water Vapour Transmission Rate (WVTR).

Advantageously, the first plate 101 and the second plate 105 are made of a material comprising from 50% to 70% by weight of glass to meet as closely as possible to the requirements for the thermomechanical parameters E and CTE.

For example, the first plate 101 and the second plate 105 are made of glass fibre and resin composites or glass fibre and polymer composites. For example, it is an epoxy or acrylic resin, a thermoplastic polymer, such as a thermoplastic polyolefin like polypropylene (PP), an ionomer, a polyamide, a polyvinyl chloride, a (meth)acrylate, a polycarbonate, a fluoropolymer or a polyester such as polyethylene terephthalate (PET or PETG).

The glass fibres advantageously represent from 55% to 65% in weight of the composite material. They can be woven (uni- or bi-directional) or non-woven.

The materials of the first and second plates can be different from each other, provided that they remain similar in terms of Young's modulus E and coefficient of thermal expansion CTE.

Preferentially, the materials of the first and second plates are identical.

The first plate 101 and the second plate 105 have a thickness from 0.25 to 3.0 millimetres (mm), advantageously from 0.5 to 1.5 mm.

The first plate 101 and the second plate 105 can have the same or different thicknesses. Preferentially, they have the same thickness.

The first plate 101 at the front side, facing the active sides of the active elements 110, is transparent, in order to let the sun's rays through. By “transparent”, it is meant in the present description that the first plate 101 is formed by a material that allows more than 70% of the incident radiation to pass through, and preferably at least 80% of the incident radiation, in the visible spectrum.

The second plate 105 positioned at the back side can be opaque or transparent.

### First Outer Encapsulating Film 102 and Second Outer Encapsulating Film 104:

The first outer encapsulating film 102 and the second outer encapsulating film 104 are made of materials having mean Young's moduli, preferably from 100 to 800 MPa, more preferentially from 200 to 600 MPa.

The outer encapsulating films 102, 104 have a mean mechanical rigidity, are moderately deformable and resistant to impact.

They are made of materials having a mean coefficient of thermal expansion of 200×10⁻⁶/K to 700×10⁻⁶/K, preferably of 300×10⁻⁶/K to 600×10⁻⁶/K. They have a mean dimensional stability under temperature variations.

The materials of the outer encapsulating films 102, 104 can be different from each other, provided that they remain similar in terms of Young's modulus E and coefficient of thermal expansion CTE.

Preferentially, the outer encapsulating films 102, 104 have a Young's modulus E of the order of 500 MPa and a coefficient of thermal expansion CTE of the order of 400×10⁻⁶/K.

The outer encapsulating films 102, 104 are advantageously made of materials for reinforcing the barrier function of the materials of the protective plates (or films), against external influences (particularly humidity).

For example, the outer encapsulating films 102, 104 are made of polymers, such as homopolymers or copolymers of ethylene vinyl acetate (EVA), ethylene methylacrylate (EMA), ethylene butylacrylate (EBA), ethylene propylene (EPDM), polyvinyl butyral (PVB), polydimethylsiloxanes, polyurethanes (PU), thermoplastic polyolefins, ionomers, polypropylene (PP), polyamide, polyvinyl chloride, polycarbonate, fluorinated polymers, or a polyester such as polyethylene terephthalate (PET or PETG). Preferably, it is an ionomer.

Preferably, herein, the materials of the two outer encapsulating films are identical.

The first outer encapsulating film 102 and the second outer encapsulating film 104 have a thickness between 0.25 mm and 1.0 mm, preferably between 0.25 mm and 0.75 mm.

Preferentially, the first outer encapsulating film 102 and the second outer encapsulating film 104 have the same thickness.

### Inner Encapsulating Film 103:

The material of the inner encapsulating film 103 has a low Young's modulus, less than that of the outer encapsulating films 102, 104. Its Young's modulus E₃ is here between 5 and 100 MPa, preferably between 10 and 50 MPa.

The inner encapsulating film 103 has a low mechanical rigidity, a good deformation capacity to be able to absorb mechanical stresses and impacts. The mechanical stability of the whole structure is ensured by the other layers of the functional device 100.

The material of the inner encapsulating film 103 has a high coefficient of thermal expansion, preferably between 800 and 2000×10⁻⁶/K, even more preferentially between 800 and 1400×10⁻⁶/K.

Preferably, the material is characterized by a Young's modulus E₃ of the order of 20 MPa and a coefficient of thermal expansion CTE₃ of the order of 900×10⁻⁶/K.

The inner encapsulating film 103 is for example an encapsulating material commonly used in the photovoltaic field.

It may be a polymer material, such as homopolymers or copolymers of ethylene vinyl acetate (EVA), ethylene methylacrylate (EMA), ethylene butylacrylate (EBA), ethylene propylene (EPDM), polyvinyl butyral (PVB), polydimethylsiloxanes, polyurethanes (PU), thermoplastic polyolefins, ionomers, polypropylene (PP), polyamide, polyvinyl chloride, polycarbonate, fluorinated polymers, or a polyester such as polyethylene terephthalate (PET or PETG). It may also be a resin of the (meth)acrylic type, or a heat or photochemically cross-linkable silicone. Preferably, it is a thermoplastic polyolefin (TPO).

The inner encapsulating film 103 has a thickness between 0.4 and 2.0 mm, preferably between 0.8 and 1.4 mm.

The inner encapsulating film 103 can have a high resistance to water penetration, a high intrinsic stability against structural degradation by water molecules and a high resistance to exposure to chemical fluids.

Advantageously, herein, the resistance of the various materials to moisture penetration increases from the inner encapsulating film 103 to the protective plates (or films) 101 and 105, at the front side and the back side.

### Electrically or Optically Active Elements 110:

The functional device 100 comprises at least one electrically or optically active element 110, or preferably a plurality of electrically or optically active elements 110, as shown in FIG. 1.

In this description, it is meant by “electrically active element” an element that transmits and/or receives electrical signals. It is meant by “optically active element” an element that transmits and/or receives optical signals, or an element that transforms optical signals into electrical signals, or vice versa.

According to a first embodiment, the electrically or optically active elements 110 are arranged between the inner encapsulating film 103 and the second outer encapsulating film 104.

As an alternative, the electrically or optically active elements 110 are arranged between the inner encapsulating film 103 and the first outer encapsulating film 102.

As another alternative, the electrically or optically active elements 110 are completely embedded, centred or not, in the thickness of the inner encapsulating film 103 (as shown in FIGS. 1 to 3).

The electrically or optically active elements could also, according to another alternative, be embedded in the second outer encapsulating film 104. As another alternative, the electrically or optically active elements could be embedded in the first outer encapsulating film 102.

The optically active elements are for example light-emitting diodes, or a photosensitive sensor (such as a photodiode).

According to a particular embodiment, here, the active elements 110 are, for example, photovoltaic cells. They are, for example, based on mono-crystalline, multi-crystalline or quasi-mono-crystalline silicon wafers, also known as “mono-like” wafers.

The photovoltaic cells are arranged side by side. Advantageously, here, the photovoltaic cells are evenly spaced apart from each other.

The photovoltaic cells are generally interconnected to each other, by electrically conductive metal connections, intended to collect the electricity generated by the photovoltaic cells. The electrically conductive connectors, also called electrically conductive parts in the present description, are metal connections attached to the metallization of the cell. For example, these are flat ribbons or copper wires. The connection is made for example by welding or gluing. The assembly formed by the photovoltaic cells and the connectors forms a skeleton of interconnected photovoltaic cells.

Advantageously, according to the invention, one of these electrically conductive connectors of the skeleton of photovoltaic cells (represented as the electrically conductive connector 150 in FIGS. 1 to 3 and 5) is connected, electrically, to an electrical connection element 160 for transporting the electricity generated from or to the active elements 110.

As shown in FIGS. 1 to 3 and 5, a free end 162 of the electrical connection element 160 exits directly from the functional device 100. In other words, this electrical connection element 160 allows direct transport of electricity between the active elements 110 and the outside of the functional device 100 without an intermediate junction box, on the back side or on the front side, of the functional device 100.

Therefore, advantageously, according to the invention, the electrical connection element 160 is connected to the active elements 110. It is integrated in the multilayer stack and exits, also directly, from the functional device 100, without the intermediate junction box, on the back side or the front side, of the functional device 100.

In the case where the active elements 110 are photovoltaic cells, the functional device 100 also comprises at least one bypass diode 120 (FIG. 5). Preferably, the functional device comprises a plurality of bypass diodes.

These bypass diodes 120 are embedded in the encapsulating assembly 107 at the same level as the active elements 110, according to the different embodiments described hereinabove for the positioning of the active elements 110 inside the encapsulating assembly 107.

As an alternative, the bypass diodes can be mounted on a support, such as a Printed Circuit Board (PCB), for example.

Advantageously, the bypass diode used has a small thickness, i.e. a thickness compatible with the thickness of the encapsulating assembly 107. Preferably, the thickness of the bypass diodes is close to the thickness of the active elements 110.

In the case of the alternative mentioned hereinabove and using a printed circuit on which the bypass diodes are mounted, the assembly formed by the printed circuit and the bypass diodes has advantageously a small thickness, i.e. a thickness compatible with the thickness of the encapsulating assembly, also preferably a thickness close to the thickness of the active elements.

These bypass diodes are connected to the skeleton of photovoltaic cells. More particularly, as shown in FIG. 6, the bypass diodes 120 are arranged in an electrical diagram in parallel with the photovoltaic cells (similar to the conventional diagram for photovoltaic modules).

Advantageously, according to the invention, several bypass diodes are interconnected, in parallel with each other in the electrical diagram (FIG. 6). Thanks to the division of the electrical current by this plurality of bypass diodes in parallel, this arrangement makes it possible to reduce the ohmic heating of each of the individual bypass diodes. This also allows the total thermal load to be spread over a larger area, thereby limiting the maximum temperature reached in the materials of the encapsulating assembly.

Therefore, this arrangement makes it possible to eliminate the need for a conventional intermediate junction box on the external envelope of the functional device while keeping functions of the latter thanks to the integration of the electrical connection element and the bypass diodes directly in the functional device, and more particularly in the multilayer stack.

The electrical connection element 160 is for example an electrical cable. Conventionally, an electrical cable 160 is formed by a conductive part formed, for example, by several wires made of conductive material, and an outer sheath, an insulating part embedding the various wires made of conductive material. For example, herein, the electrical cable comprises a metal conductive part and an outer sheath is formed of a polymer material.

In the present description, a stripped metal end of the electrical cable refers to a portion of this cable without outer sheath. Therefore, the electrical connection of the electrical cable 160 to the electrically conductive connector 150 is made using a stripped metal end of the electrical cable 160. This stripped metal end is for example welded to the electrically conductive connector 150 so as to make the electrical connection.

As shown in FIGS. 1 to 3 and 5, the electrical cable 160 is integrated in the different layers of the functional device 100 in order to make a direct electrical connection between the active elements 110 and the outside of the functional device 100. The electrical cable 160 extends through the various layers of the functional device 100. More particularly, advantageously according to the invention, the encapsulating assembly 107 comprises a passage, through the encapsulating assembly 107, for the exit of the electrical connection element 160 outside the functional device 100. In the present description, it is meant by “passage” an area of the encapsulating assembly that is passed through by the electrical connection element 160.

As shown in FIGS. 1 to 3 and 5, the electrical connection element 160 is embedded in a material as it passes through the functional device 100. In practice, this embedding material is chosen for example among one or more of the materials forming the encapsulating assembly 107 (hence, herein, one or more of the materials forming the first outer encapsulating film 102, the inner encapsulating film 103 or the second outer encapsulating film 104).

According to a first embodiment shown in FIG. 1 or in FIG. 5, a first orifice 104a is formed in the second outer encapsulating film 104 and a second orifice 105a is formed in the second protective plate 105. This first orifice 104a and this second orifice 105a are aligned in such a way as to form a through-orifice 180 through the second outer encapsulating film 104 and the second protective plate 105 (a single and continuous through-orifice 180 is thus formed). This through-orifice 180 then allows the passage of the electrical cable 160. As shown in FIGS. 1 and 5, in this embodiment, the electrical cable 160 therefore exits from the functional device 100 through the back side of the latter.

In the present description, it is meant by “orifice” an opening in the form of a duct that connects the inside of the functional device to the outside thereof.

The through-orifice 180 here has the shape of a slot or a hole. This through-orifice 180 is for example made, in practice, using a drill, introduced through the second outer encapsulating film 104 and the second protective plate 105. As an alternative, this through-orifice 180 can be made using a cutting tool, or also a water jet cutting machine.

According to this first embodiment, the electrical cable 160 is therefore also integrated in the inner encapsulating film 103. As an alternative, the electrical cable can be integrated in the inner encapsulating film and the second outer encapsulating film. As another alternative, it can be integrated in the second outer encapsulating film.

In particular, the electrical connection between the electrical cable 160 and the electrically conductive connector 150 of the active elements 110 is also integrated in the inner encapsulating film 103. As an alternative, this connection can be integrated in the inner encapsulating film and the second outer encapsulating film. As another alternative, it can be integrated in the second outer encapsulating film.

The space between the electrical cable 160 and the walls of the through-orifice 180 is here filled with the same material as that of the second outer encapsulating film 104. This also ensures a seal of the functional device. There exist no areas liable to facilitate the penetration of moisture into the functional device.

As an alternative, according to a second embodiment shown in FIG. 2, a third orifice 102a is formed in the first outer encapsulating film 102 and a fourth orifice 101a is formed in the first protective plate 101. This third orifice 102a and this fourth orifice 101a are aligned in such a way as to form a through-orifice 182 through the first outer encapsulating film 102 and the first protective plate 101. This through-orifice 182 then allows the passage of the electrical cable 160. As shown in FIG. 2, in this embodiment, the electrical cable 160 therefore exits from the functional device 100 through the front side of the latter.

As for the first embodiment described hereinabove, the through-orifice 182 here has the shape of a slot or a hole. This through-orifice 182 is for example made, in practice, using a drill, introduced through the first outer encapsulating film 102 and the first protective plate 101. As an alternative, this through-orifice 182 can be made using a cutting tool, or also a water jet cutting machine.

According to this second embodiment, the electrical cable 160 is therefore also integrated in the inner encapsulating film 103.

As an alternative, the electrical cable can be integrated between the inner encapsulating film and the first outer encapsulating film. As another alternative, it can be integrated in the first outer encapsulating film.

In particular, the electrical connection between the electrical cable 160 and the electrically conductive connector 150 of the active elements 110 is integrated in the inner encapsulating film 103.

As an alternative, this connection can be integrated in the inner encapsulating film and the first outer encapsulating film. As another alternative, it can be integrated in the first outer encapsulating film.

The space between the electrical cable 160 and the walls of the through-orifice 182 is here filled with the same material as that of the first outer encapsulating film 102. This also ensures a seal of the functional device. Therefore, there are no areas liable to facilitate the penetration of moisture into the functional device.

This second embodiment is particularly advantageous for a use in which the mounting of the functional device on its support does not allow the electrical cable to exit through the back side.

As another alternative, according to a third embodiment shown in FIG. 3, the exit of the electrical cable 160 from the functional device 100 can be made through the edge of the functional device 100. More precisely, in this example, the encapsulating assembly 107 comprises a passage for the exit of the electrical cable 160 outside the functional device 100. Unlike these two first embodiments, no orifice is pierced in this third embodiment (the cable exits directly from the functional device).

In this case, the electrical cable 160, as well as its point of connection to the active elements 110, extend through the inner encapsulating film 103. In this example, the electrical cable 160 thus exits directly from the lateral side of the functional device 100.

As an alternative, the electrical cable and its point of connection to the active elements can be integrated in the inner encapsulating film and the second outer encapsulating film. As another alternative, the electrical cable and its point of connection to the active elements can be integrated between the inner encapsulating film and the first outer encapsulating film.

Advantageously, according to the invention, the electrical cable 160 has an outer sheath whose material is free from halogen elements (as for example chloride, fluorine or bromine). In particular, the outer sheath of the cable is free from fluoropolymers. As an alternative, the outer sheath of the electrical cable is free from chloropolymer and/or bromopolymer. This makes it possible to ensure a good adherence between the different materials of the encapsulating assembly of the functional device 100 and the outer sheath of the electrical cable 160. This is an essential factor to ensure a good seal and avoid the risk of delamination at the exit of the electrical cable from the functional device.

The cross-section of the electrical cable 160 integrated in the functional device 100 is determined as a function of the level of electrical current the cable will have to withstand. Advantageously, this cross-section is less than or equal to 2.5 mm², or also advantageously less than or equal 1.5 mm².

In practice, the electrical cable chosen for the present invention has range of operating temperatures compatible with the actual conditions of use of the functional device (from −40° C. to +85° C.). The electrical cable chosen is also compatible with common lamination methods (e.g. with a lamination temperature of the order of 130 to 170° C. and a pressure of the order of 1 bar) used for the photovoltaic modules. The electrical cable chosen has also a good resistance to ultraviolet radiation, humidity, ozone and chemicals such as oils, petrols and acids.

The electrical cable can also comprise flame retardants to delay the onset of flames during use.

Examples of suitable electrical cables liable to be used in the present invention are for example the following: cable Energyflex (Nexans) 2.5 mm², cable Flamex EN 50264-3-1 1.5 mm²-2.5 mm² (Nexans), cable Varpren ST 1.5 mm²-2.5 mm² (Omerin), cable Varpren 155 UL 1.5 mm²-2.5 mm² (Omerin).

As an alternative of the electrical cable, a flat metal braid can be used. This flat braid has a cross-section advantageously less than 2 mm². It is for example a 30A earthing braid.

In this case, the flat braid is covered with a resin heat-shrink sheath, e.g. a TE Connectivity heat-shrink sheath, Dia. 4.8 mm Black shrink 3:1, 300 mm. This makes it possible to protect the flat braid from humidity and to provide mechanical protection to the assembly.

As an alternative of the direct connection of the electrical cable 160 on the electrically conductive connector 150, the electrical connection can be made using an intermediate element, such as a terminal (or “lug”) 190.

FIG. 4 schematically shows such an electrical connection by means of a lug 190. For example, in the case where the electrically conductive element is a flat metal tape 155, an end of the flat tape 155 is crimped in a first flat part 192 of the lug 190. This bond is reinforced by the addition of tin on the front and back sides of the flat ribbon 155. In particular, this ensures good electrical contact between the flat tape 155 and the lug 190.

On the other side of the lug 190, the stripped metal end of the electrical cable 160 is crimped in a second part 194 of the lug 190. This second part 194 of the lug 190 has for example a diameter of the order of 4.5 mm.

The use of an intermediate element, such as a lug 190, for example, makes it possible in particular to improve the manufacturability (i.e. industrial manufacture) of the connection between the electrical cable 160 and the electrically conductive connector 150, because it allows avoiding welding directly a stripped metal end of the electrical cable on the electrically conductive element.

Examples of lugs compatible with the present invention are for example the following: RS PRO non-insulated female terminals 4-6 mm² (RS), RS PRO non-insulated blade terminals 4-6 mm² (RS), Flag Krimptite Quick Disconnect, Female, for 10-12 (3.30 to 5.00 mm²) Wire, Tab 6.35×0.81 mm (Molex) or also RS PRO Crimp Receptacle, 6.35×0.8 mm, 2.5 mm² to 6 mm², 14 AWG to 10 AWG, Tin Plated (RS), RS PRO non-insulated female terminals 1.5-2.5 mm² (RS).

### Method for Manufacturing the Functional Device 100:

Generally, the method for manufacturing the functional device 100 includes the following successive steps:
a step of connecting the electrical connection element 160 to the electrically or optically active element 110; and
a step of forming the multilayer stack for embedding the electrically or optically active element 110 into the encapsulating assembly 107 between the first protective film 101 and the second protective film 105, an end 162 of the electrical connection element 160 exiting directly from said functional device 100.

In the case where the electrically or optically active elements are photovoltaic cells, the method also comprises, before the step of forming the multilayer stack, a step of connecting at least one bypass diode 120 to the photovoltaic cells. This bypass diode 120 is mounted or not on a printed circuit support.

The bypass diode 120 is then also embedded in the encapsulating assembly 107 during the step of forming the multilayer stack.

The step of forming the multilayer stack is for example made by hot lamination. As an alternative, it can be implemented by thermocompression, infusion or also Resin Transfer Moulding (RTM).

More precisely, in the case of a first embodiment of the method for manufacturing the functional device 100 (shown in FIG. 1), le method for manufacturing the functional device 100 comprises, in this order, the following steps:
positioning the second protective film 105, arranged on the back side of said functional device 100,
positioning the encapsulating assembly,
forming the through-orifice 180 through said encapsulating assembly and said second protective film 105 for the passage of the electrical connection element 160 through said functional device 100,
positioning the electrical connection element 160 and the electrically or optically active element 110, the electrical connection element 160 passing through the through-orifice 180 so that an end 162 of the electrical connection element 160 exits directly from the functional device,
connecting the electrical connection element 160 to the electrically or optically active element 110,
positioning the first protective film 101, arranged on the front of said functional device 100, and
hot laminating the assembly.

According to this first embodiment, the functional device 100 is thus manufactured by stacking from the back side to the front side of the device.

In this embodiment, the method also comprises a step of providing a Teflon layer, temporarily during the lamination, positioned between the second protective film 105 and a portion of the electrical connection element 160 exiting from said operating device 100. This Teflon layer prevents the electrical connection element 160 from being irreversibly embedded in the second protective film 105 during the manufacturing process.

According to a second embodiment of the method for manufacturing the functional device 100 (shown in FIG. 2), le method for manufacturing the functional device 100 comprises, in this order, the following steps:
positioning the first protective film 101, arranged on the front of said functional device 100,
positioning the encapsulating assembly 107,
forming a through-orifice 182 through said encapsulating assembly 107 and said first protective film 102 for the passage of the electrical connection element 160 through said functional device,
positioning the electrical connection element 160 and the electrically or optically active element 110, the electrical connection element 160 passing through the through-orifice 182 so that an end 162 of the electrical connection element 160 exits directly from the functional device,
connecting the electrical connection element 160 to the electrically or optically active element 110,
positioning the second protective film 105, arranged on the back of said functional device 100, and
hot laminating the assembly.

According to this second embodiment, the functional device 100 is thus manufactured by stacking from the front side to the back side of the functional device 100.

According to a third embodiment of the method for manufacturing the functional device 100 (shown in FIG. 3), le method for manufacturing the functional device 100 comprises, in this order, the following steps:
positioning the second protective film 105, arranged on the back of said functional device 100,
positioning the encapsulating assembly so as to form a passage in the encapsulating assembly, the passage allowing the exit of the electrical connection element outside the functional device 100,
positioning the electrical connection element 160 and the electrically or optically active element 110, the electrical connection element 160 extending through the passage formed in the encapsulating assembly so that an end 162 of the electrical connection element 160 exits directly from the functional device,
connecting the electrical connection element 160 to the electrically or optically active element 110,
positioning the first protective film 101, arranged on the front of said functional device 100, and
hot laminating the assembly.

As an alternative, for this third embodiment of the method for manufacturing the functional device 100 (shown in FIG. 3), le method for manufacturing the functional device 100 comprises, in this order, the following steps:
positioning the first protective film 101, arranged on the front of said functional device 100,
positioning the encapsulating assembly so as to form a passage in the encapsulating assembly, the passage allowing the exit of the electrical connection element outside the functional device 100,
positioning the electrical connection element 160 and the electrically or optically active element 110, the electrical connection element 160 extending through the passage formed in the encapsulating assembly so that an end 162 of the electrical connection element 160 exits directly from the functional device,
connecting the electrical connection element 160 to the electrically or optically active element 110,
positioning the second protective film 105, arranged on the back of said functional device 100, and
hot laminating the assembly.

In other words, this third embodiment of the manufacturing method can be implemented, indifferently, by stacking from the back side to the front side of the device, or the reverse.

The through-orifice allows the passage of the electrical connection element so that the free end 162 thereof exits from the functional device 100 (the other end being connected to an electrically conductive element linked to the electrically or optically active element). The through-orifice is made in the layers concerned by a drilling operation, for example using a drill or a cutting tool or a water jet cutting machine, as mentioned hereinabove.

Hot lamination of the assembly (also called laminage) not only melts and then cross-links or polymerises the polymer materials but also ensures good adhesion between all the layers, the electrically or optically active elements and the electrical connection element forming the whole structure.

Each encapsulating film 102, 103 and 104; as well as the protective plates or films 101 and 105; can be obtained from one or more stacked layers of a same material; in order to obtain the desired thickness for each film or plate in its final state; after lamination.

The lamination is executed using a so-called laminator (also called roll mill), which may be for example a membrane press or a double-plate press.

The lamination process is carried out hot under vacuum and mechanical pressure. The lamination temperature is between 120° C. and 200° C., and advantageously between 140° C. and 170° C., with an adjustable process time. This process time is for example between 15 and 30 minutes. The pressure applied is typically of the order of one bar.

### Applications

The present invention advantageously relates to the functional devices for solar roads, and in particular the photovoltaic modules. The invention also advantageously applies to functional devices intended to be positioned on a roadway and integrating other electrically or optically active or passive elements.

In particular, the functional device 100 can be integrated at the surface of trafficable roadways—for any motorised and/or non-motorised wheeled and/or pedestrian transport means. More details about the characteristics of such a roadway can be found in the document FR3093116.

The invention also advantageously applies to the transport vehicles, such as motor vehicles, trains or boats. The functional device according to the invention is for example integrated at an external surface of a transport vehicle.

Finally, the invention also finds a privileged application in all the usual fields in which photovoltaic modules are included. In particular, the functional device according to the invention can be integrated at the surface of a building envelope. By “building envelope, it is here meant the roof or the facade of a building. The functional device according to the invention can advantageously be installed on a flat roof or an inclined roof.

1. A functional device including a multilayer stack comprising, in succession:
a first, transparent, protective film, arranged on the front side of said device,
an encapsulating assembly,
a second protective film, transparent or not, arranged on the back side of the device,
at least one electrically or optically active element embedded in the encapsulating assembly, and
an electrical connection element connected to said electrically or optically active element and suitable for transporting electricity from or to said electrically or optically active element,
wherein the electrical connection element is integrated into the multilayer stack,
in that said electrical connection element comprises an outer sheath free from halogen elements and an end of which exits directly from said functional device, so as to eliminate the need for an intermediate junction box on the front side or the back side of the functional device.

2. The functional device according to claim 1, wherein the electrically or optically active element is a photovoltaic cell, said photovoltaic cell being connected to at least one bypass diode embedded in the encapsulating assembly.

3. The functional device according to claim 1, wherein the outer sheath of the electrical connection element is free from fluoropolymer or chloropolymer or bromopolymer.

4. The functional device according to claim 1, wherein the encapsulating assembly comprises a passage for the exit of the electrical connection element, through the encapsulating assembly, outside the functional device.

5. The functional device according to claim 1, wherein the encapsulating assembly comprises:
a first outer encapsulating film,
an inner encapsulating film, and
a second outer encapsulating film.

6. The functional device according to claim 5, wherein the electrical connection element is embedded in an encapsulating material along its passage through said functional device, said encapsulating material being chosen among one or more of the materials forming the first outer encapsulating film, the inner encapsulating film or the second outer encapsulating film.

7. The functional device according to claim 5, wherein the second outer encapsulating film comprises a first orifice and the second protective film comprises a second orifice, the first orifice and the second orifice being aligned in such a way as to form a through-orifice for the passage of the electrical connection element through the second outer encapsulating film and the second protective film.

8. The functional device according to claim 7, wherein a space between walls of said through-orifice and the electrical connection element passing through said through-orifice is filled with the same material as that forming the second outer encapsulating film.

9. The functional device according to claim 5, wherein the first outer encapsulating film comprises a third orifice and the first protective film comprises a fourth orifice, the third orifice and the fourth orifice being aligned in such a way as to form a through-orifice for the passage of the electrical connection element through the first outer encapsulating film and the first protective film.

10. The functional device according to claim 9, wherein a space between walls of said through-orifice and the electrical connection element passing through said through-opening is filled with the same material as that forming the first outer encapsulating film.

11. The functional device according to claim 5, wherein a passage for the exit of the electrical connection element through the inner encapsulating film is included in the inner encapsulating film or between the first outer encapsulating film and the inner encapsulating film or between the inner encapsulating film and the second outer encapsulating film.

12. The functional device according to claim 1, wherein a stripped metal end of said electrical connection element is directly welded to an electrically conductive part of said electrically or optically active element.

13. The functional device according to claim 1, wherein a stripped metal end of the electrical connection element is connected to an electrically conductive part of said electrically or optically active element by means of an intermediate connection element, e.g. a flat copper tape.

14. The functional device according to claim 12, wherein the intermediate connection element comprises a terminal.

15. The functional device according to claim 1, wherein the electrical connection element is a round electrical cable.

16. The functional device according to claim 1, wherein the electrical connection element is a flat metal braid covered with a heat-shrinkable sheath.

17. The functional device according to claim 1, wherein the electrical connection element has a cross-section less than or equal to 2.5 mm².

18. A functionalised trafficable or pedestrian roadway, comprising a trafficable or pedestrian roadway on which is fastened a functional device as defined in claim 1.

19. A transport vehicle comprising a functional device according to claim 1.

20. A building envelope comprising a functional device according to claim 1.

21. A method for manufacturing a functional device according to claim 1, said method comprising:
a step of connecting the electrical connection element to the electrically or optically active element; and
a step of forming the multilayer stack for embedding the electrically or optically active element into the encapsulating assembly between the first protective film and the second protective film, an end of the electrical connection element exiting directly from said functional device.

22. The manufacturing method according to claim 21, wherein the step of forming the multilayer stack is made by hot lamination.

23. The manufacturing method according to claim 21, comprising a step of forming a passage into said encapsulating assembly, said passage allowing the exit of the electrical connection element through said encapsulating assembly.

24. The manufacturing method according to claim 21, comprising a step of forming a through-orifice through said encapsulating assembly and said second protective film for the passage of the electrical connection element through said functional device.

25. The manufacturing method according to claim 21, comprising a step of forming a through-opening through said encapsulating assembly and said first protective film for the passage of the electrical connection element through said functional device.
